(19) United States
(12) Patent Application Publication
(10) Pub. No.: US 2003/0008468 A1
(43) Pub. Date: Jan. 9, 2003

(54) Method of fabricating capacitor in semiconductor device and the capacitor

(76) Inventor: Won Kyu Park, Suseong-gu (KR)

Correspondence Address: BIRCH STEWART KOLASCH & BIRCH, PO BOX 747, FALLS CHURCH, VA, 22040-0747, US

(21) Appl. No.: 10/124,477

(22) Filed: Apr. 18, 2002

(30) Foreign Application Priority Data
Apr. 19, 2001 (KR) 2001-21187

(51) Int. Cl. H01L 21/8242; H01L 21/20

(52) U.S. Cl. 438/393; 438/381; 438/239; 438/250

(57) ABSTRACT

The method includes forming a first insulating interlayer on a semiconductor substrate having a transistor thereon, depositing first to third metal layers on the first insulating interlayer, and depositing a first insulating layer on the third metal layer. Then, the first insulating layer is oxidized. A fourth metal layer is deposited on the first insulating layer. Selective etching is performed on the first insulating layer and the fourth metal layer to expose a predetermined portion of the third metal layer. Selective etching of the first to third metal layers then takes place to expose a surface of the first insulating interlayer. A second insulating layer is deposited over the substrate, and contact holes are formed by selectively removing the second insulating layer to expose the third and fourth metal layers. Metal plugs are formed in the contact holes, and a metal wire connected to each metal plug is formed.

### BACKGROUND OF THE INVENTION

1. Field of the Invention

The present invention relates to a method of fabricating a capacitor in a semiconductor device and the capacitor, and more particularly, to a method of fabricating an MIM type capacitor in a semiconductor device.

2. Background of the Related Art

An MML(merged memory logic) device includes a memory cell array part such as DRAM (dynamic random access memory), and an analog or a peripheral circuit, which are integrated on one chip together.

PIP (poly-insulator-poly) type capacitors in a memory cell array and an analog circuit use electrically-conductive polysilicon for forming lower and upper electrodes, whereby oxidation occurs at an interface between the upper/lower electrodes and a dielectric layer so as to form natural oxide therebetween. Thus, capacitance of the capacitor is reduced.

In order to overcome this problem, MIS(metal-insulator-silicon) or MIM (metal-insulator-metal) type capacitors have been proposed. The MIM type capacitor has low specific resistance and no parasitic capacitance caused by depletion inside, these capacitors are used for high performance semiconductor devices.

However, the MIM type analog capacitor, which has to be realized together with other semiconductor devices, needs to be connected to a semiconductor device through a metal wire, an interconnection line.

Explained below is a method of fabricating a capacitor in a semiconductor device according to a related art. FIGS. 1A to FIGS. 1G illustrate cross-sectional views of fabricating an MIM type capacitor in a semiconductor device according to a related art, and FIG. 2A and FIG. 2B illustrate layouts of capacitor areas when forming contacts using the dry etch process shown in FIG. 1B.

Referring to FIG. 1A, transistors (not shown in the drawing) and bit lines (not shown in the drawing) are formed on a semiconductor substrate 11 where a memory area and an analog area are defined.

After a first insulating interlayer 12 has been deposited on a front surface of the substrate 11 including the transistors and bit lines, a first metal layer 13, a barrier layer 14 and an anti-reflection layer 15 are deposited successively on the first insulating interlayer 12, which is also planarized. In this case, the first metal layer 13 is formed of Al, of which the deposited thickness is 500 Å, and the barrier metal layer 14 is formed of Ti, of which the deposited thickness is 100 Å. And, the anti-reflection layer 15 is formed of TiN, of which the thickness is 600 Å.

Subsequently, a first photoresist 16 is coated on the antireflection layer 15. The first photoresist 16 is then patterned by exposure and development.

The first metal layer 13, the barrier metal layer 14, and the anti-reflection layer 15 are selectively etched by an etching process using the patterned first photoresist 16 as a mask, thereby forming a lower electrode 13a of a capacitor and a first metal wire 13b. In this case, the first metal layer 13, the barrier metal layer 14, and the anti-reflection layer 15 are selectively etched using a dry etch.

Referring to FIG. 1B, after the patterned first photoresist 16 has been removed, a second insulating interlayer 17 is deposited on an entire surface of the substrate 11 including the lower electrode 13a and the first metal wire 13B. The second insulating interlayer 17 is then planarized. In this case, the second insulating interlayer 17 is formed of IMO(inter-metal oxide).

Having been coated on the second insulating interlayer 17, a second photoresist 18 is patterned by exposure and development. A first contact hole 19 is then formed by etching the second insulating interlayer 17 so as to expose a portion of the anti-reflection layer 15 on the lower electrode 13a. In this case, the second insulating interlayer 17 is etched selectively using a dry etching process and the anti-reflection layer 15 is exposed so as to form a capacitor in a following process.

Meanwhile, if the dry etching process is used for forming the first contact hole 19, as shown in FIG. 2A, corners of the first contact hole 19 have a rounded shape so as to bring about an area size variance. In order to reduce such a variance, a polygonal pattern may be alternatively used as shown in FIG. 2B instead of a square pattern shown in FIG. 2A. However, since the polygonal pattern has a smaller area size in a fixed cell area than the square pattern has, a cell area required for a capacitor with the polygonal pattern should increase to obtain a desired capacitance.

Referring to FIG. 1C, after the patterned second photoresist 18 has been removed, a PE-TEOS (tetraethylorthosilicate) 20 is deposited on the second insulating interlayer 17 including the first contact hole 19 by a low temperature process. In this case, the PE-TEOS 20 is deposited about 310 Å thick so as to meet a density of 1.0 fF/μm² of capacitance. And, the PE-TEOS 20 is used as a dielectric layer.

Referring to FIG. 1D, a third photoresist 21 is formed on the PE-TEOS 20. The third photoresist 21 is then patterned using exposure and development. Then, second contact holes 22 and 22′ are formed by etching the PE-TEOS 20 and the second insulating interlayer 17 selectively so as to expose portions of the anti-reflection layer 15 on the lower electrode 13a and the anti-reflection layer 15 on the metal wire 13b by an etching process using the third photoresist 21 as an etch mask.

In this case, the PE-TEOS 20 and the second insulating interlayer 17 are etched using a dry etching process.

Referring to FIG. 1E, after the patterned third photoresist 21 has been removed, second, third, and fourth metal layers 23, 24, and 25 are successively deposited on the PE-TEOS 20 including the second contact holes 22 and 22′. In this case, the second metal layer 23 is formed of Ti, of which the thickness is 100 Å, the third metal layer 24 is formed of TiN, of which the thickness is 150 Å, and the fourth metal layer 25 is formed of W, of which the thickness is 5000 Å.

In this case, the second metal layer 23 formed in the second contact holes 22 and 22′ is formed of pure metal so as to improve a contact characteristic between the second metal layer 23 and the first metal wire 13b. Yet, leakage current tends to occur from a capacitor electrode due to the unstable nature of an oxide layer interface.

Referring to FIG. 1F, the second to fourth metal layers 23 to 25 are planarized so as to remain only in the first and second contact holes 19, 22 and 22′ by carrying out CMP (Chemical Mechanical Polishing) on the second to fourth metal layers 23 to 25. Thus, the remaining second to fourth metal layers 23 to 25 in the first and second contact holes 19, 22 and 22′ are isolated from each other.

In this case, the second to fourth metal layers 23 to 25 formed on the PE-TEOS 20 in the first contact hole 19 become an upper electrode, and the second to fourth metal layers 23 to 25 formed in the second contact holes 22 and 22′ become a plug metal layer.

Referring to FIG. 1G, a fifth metal layer 26 is deposited on the PE-TEOS layer 20 including the fourth metal layer 25. The fifth metal layer 26 is then selectively etched by photolithography using a dry etching process so as to form second metal wires 26.

Unfortunately, in the MIM type capacitor according to the related art, corners of the MIM type capacitor become rounded to change its area when the lower electrode is exposed by the dry etching process. In order to reduce such a size variance, if a polygonal pattern is used, the area variance is reduced but a cell area required for a capacitor increases.

Moreover, when the dielectric layer is formed of an oxide layer and Ti is used for a contact characteristic of the metal wire in a logic area of the MML semiconductor device, leakage current occurs at an electrode of a capacitor due to an unstable junction of a dielectric layer interface in a memory area.

### SUMMARY OF THE INVENTION

Accordingly, the present invention is directed to a method of fabricating a capacitor in a semiconductor device and the capacitor that substantially obviates one or more of the problems due to limitations and disadvantages of the related art.

The object of the present invention is to provide a method of fabricating a capacitor in a semiconductor device that reduces leakage current as well as improves capacitance.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages, and in accordance with the purpose of the present invention as embodied and broadly described, a method of fabricating a capacitor in a semiconductor device according to the present invention includes the steps of forming a first insulating interlayer on a semiconductor substrate having a transistor thereon, depositing first to third metal layers on the first insulating interlayer successively, depositing a first insulating layer on the third metal layer, oxidizing a surface of the first insulating layer, depositing a fourth metal layer on the first insulating layer, selectively etching the first insulating layer and the fourth metal layer so as to expose a predetermined portion of the third metal layer, selectively etching the first to third metal layers so as to expose a surface of the first insulating interlayer, depositing a second insulating layer over the substrate, forming a plurality of contact holes by selectively removing the second insulating layer so as to expose the third and fourth metal layers, forming a metal plug in each of the contact holes, and forming metal wires respectively connected to the metal plugs.

Preferably, the first metal layer is formed of Al, of which a thickness is 4500 to 5500 Å; the second metal layer is a barrier metal layer formed of Ti, of which a thickness is 50 to 150 Å; the third metal layer is an anti-reflective coating layer formed of TiN, of which a thickness is 500 to 700 Å; and the first insulating layer is formed of PE-N of which a thickness is 500 to 700 Å.

Preferably, the first insulating layer is a dielectric layer and the step of oxidizing a surface of the first insulating layer is carried out by injecting 03 at a temperature of 250 to 350 Å. Also, the fourth metal layer serves as an upper electrode of the capacitor and is formed of TiN, of which a thickness is 1100 to 1300 Å. The steps of etching the first insulating layer, the fourth metal layer, the second metal layer, and the third metal layer are preferably carried out using dry etch.

Preferably, the step of selectively etching the first to third metal layers so as to expose a surface of the first insulating interlayer is carried out to define a metal wire and a lower electrode.

Preferably, the step of forming a metal plug includes the steps of depositing a plug metal layer on the second insulating interlayer including the contact holes, and removing the plug metal layer by etch-back so as to remain only in the contact holes.

More preferably, the contact holes are formed by dry etch and the dry etch is carried out until a thickness of the third metal layer is at least 300 to 500 Å thick.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIGS. 1A to FIGS. 1G illustrate cross-sectional views of fabricating a MIM type capacitor in a semiconductor device according to a related art;

FIG. 2A and FIG. 2B illustrate layouts of capacitor areas when forming contacts using the dry etch in FIG. 1B; and

FIGS. 3A to FIGS. 3F illustrate cross-sectional views of fabricating a capacitor in a semiconductor device according to an embodiment of the present invention.

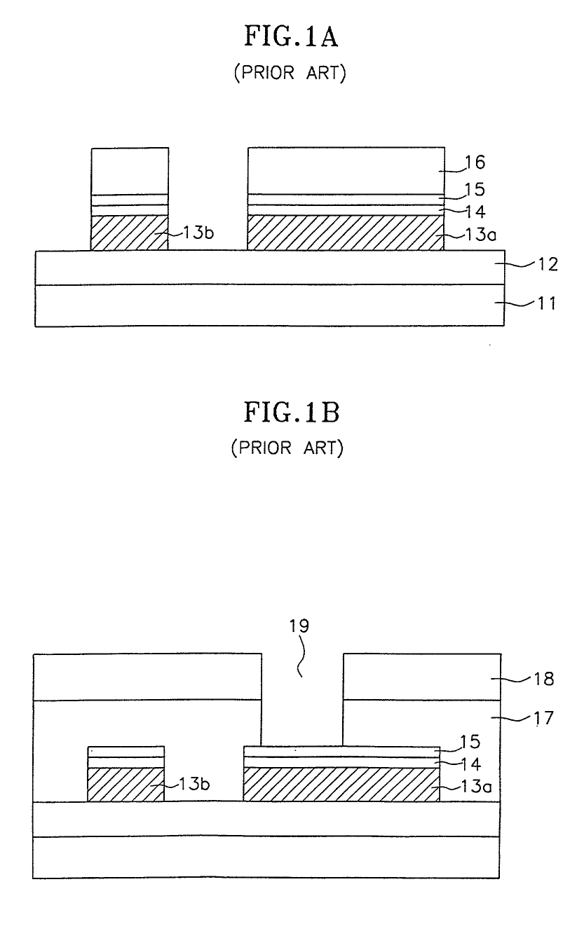

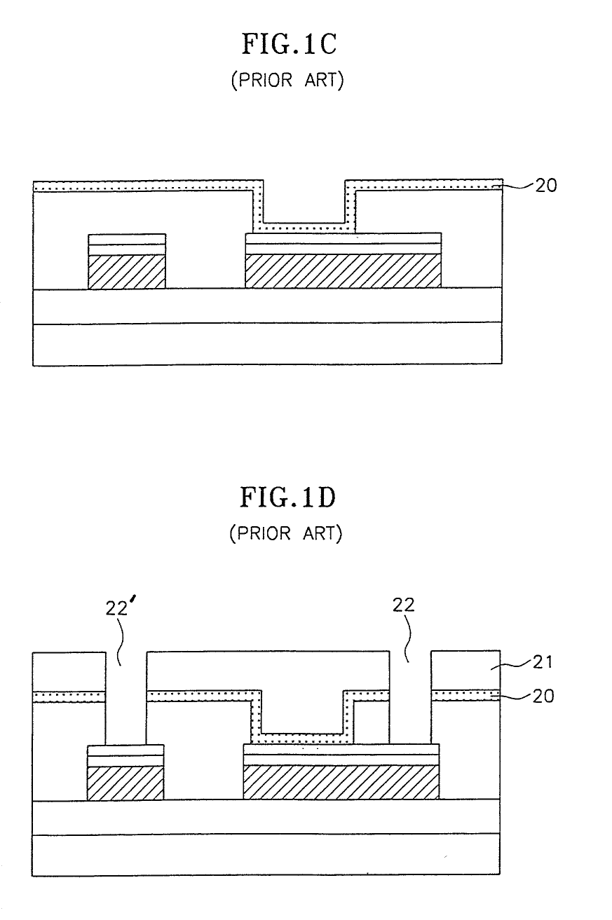

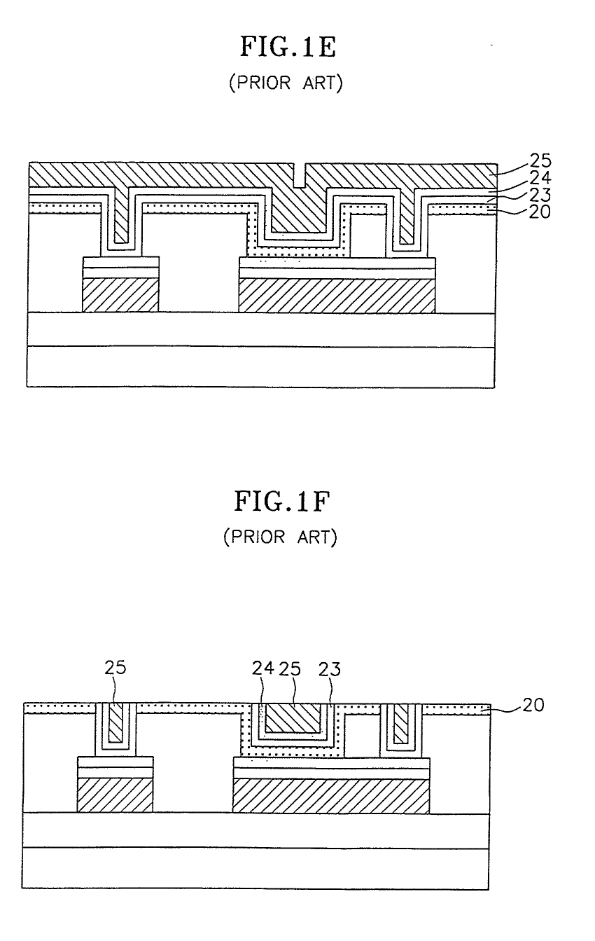

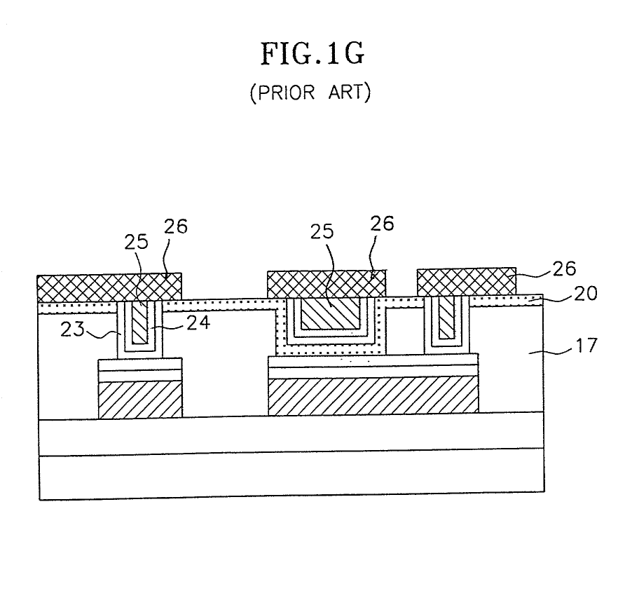

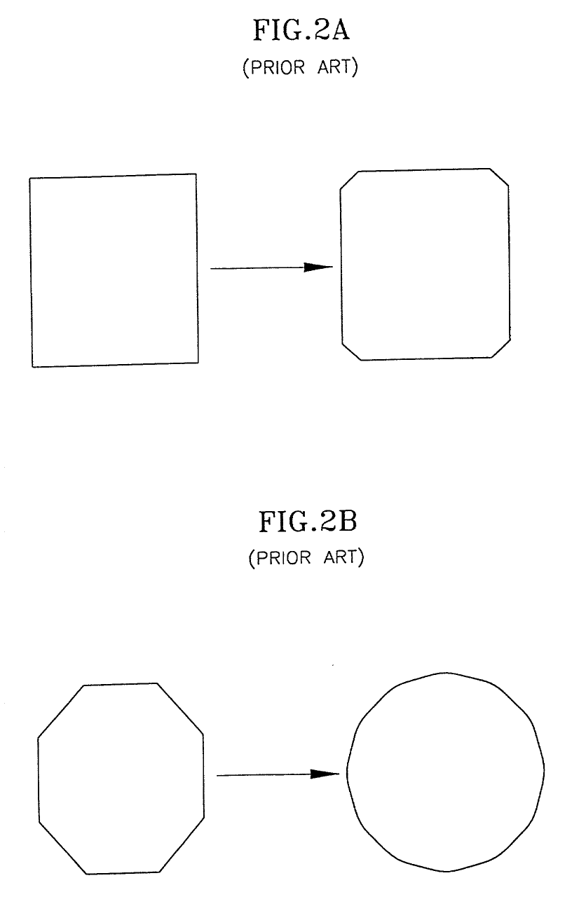

### DETAILED DESCRIPTION OF THE PREFERRED EMBODIMENTS

Reference will now be made in detail to the preferred embodiments of the present invention, examples of which are illustrated in the accompanying drawings. Where possible, the same reference numerals will be used to illustrate like elements throughout the specification.

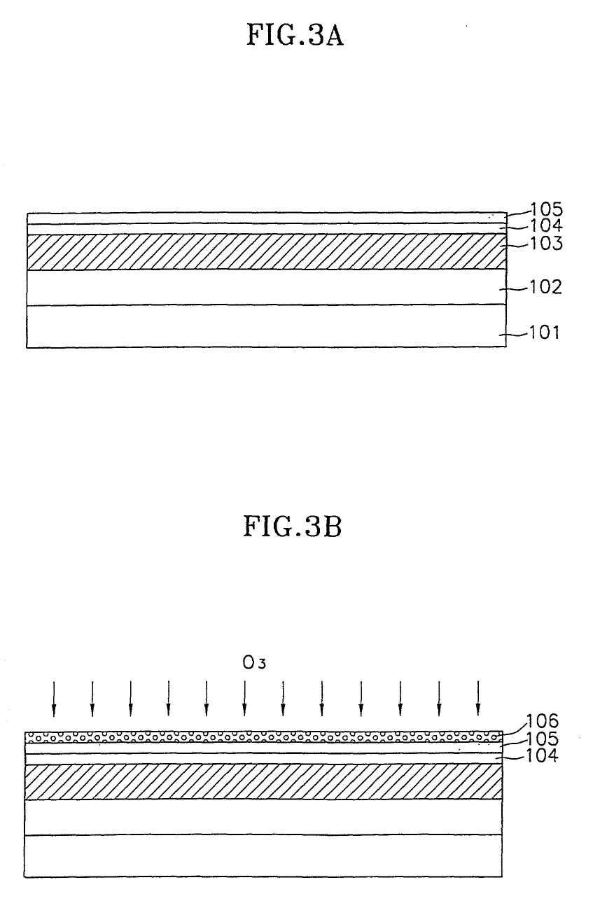

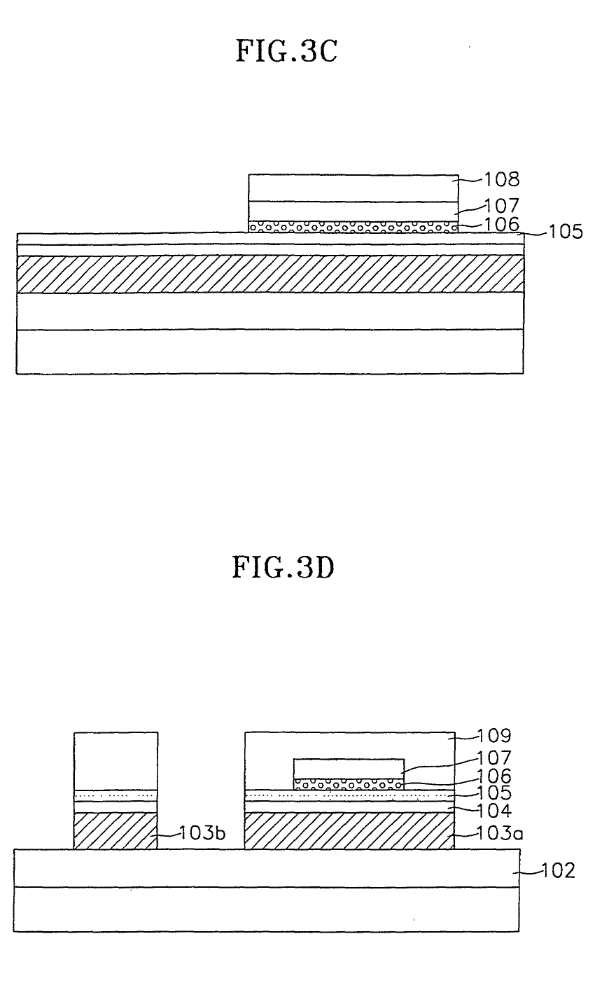

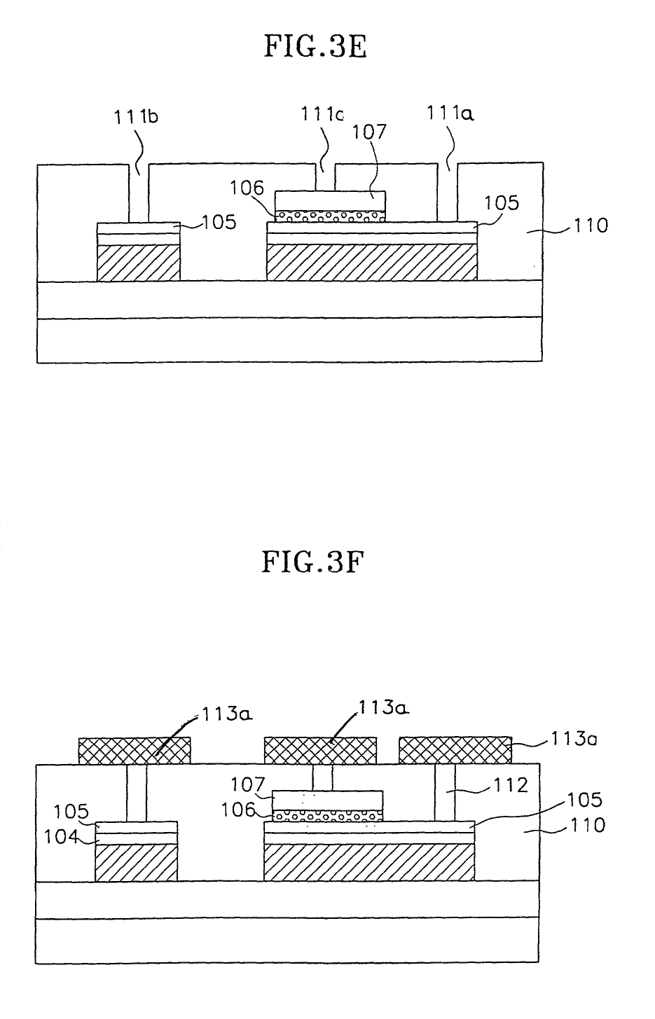

FIGS. 3A to FIGS. 3F illustrate cross-sectional views of fabricating a capacitor in a semiconductor device according to an embodiment of the present invention.

Referring to FIG. 3A, a first insulating interlayer 102 is formed on a semiconductor substrate 101 having a transistor (not shown). First to third metal layers 103 to 105 are deposited on the first insulating interlayer 102 in order. In this case, the first metal layer 103 is formed of Al, of which the thickness is 4500 to 5500 Å. The second metal layer 104 is formed of Ti, of which the thickness is 50 to 150 Å. And, the third metal layer 105 is formed of TiN, of which the thickness is 500 to 700 Å.

Moreover, the second metal layer 104 is a barrier metal layer and the third metal layer 105 is an ARC(anti-reflective coating) layer.

Also, the third metal layer 105 helps improve an interface characteristic with a dielectric layer to be formed in a succeeding process.

Referring to FIG. 3B, a PE-N(nitride) 106 is deposited on the third metal layer 105 at a low temperature. An upper surface of the PE-N 106 is oxidized by flowing O₃ thereon at a temperature of 250 to 350 μm. In this case, the PE-N 106 is a dielectric layer of a capacitor, of which the thickness is set to 500 to 700 Åso as to meet a 1.0 f/Fμm² density of capacitance.

Degradation of the metal layer due to heat is prevented by using the low temperature PE-N 106. The reason why the PE-N 106 is oxidized is to prevent leakage current caused by column-row phenomenon of a nitride layer.

Also, deposition uniformity of the nitride layer 106 on a wafer is excellent, thereby enabling to secure a matching characteristic between chips.

Referring to FIG. 3C, a fourth metal layer 107 is deposited on the oxidized PE-N 106. A first photoresist 108 is formed on the fourth metal layer 107. The first photoresist 108 is then patterned using exposure and development. In this case, the fourth metal 107 is formed of TiN, of which the thickness is 1100 to 1300 Å.

Subsequently, an upper electrode of a capacitor is defined by selectively removing the PE-N 106 and the fourth metal layer 107 so as to expose the third metal layer 105 by an etching process using the patterned first photoresist 108 a mask. In this case, the etching process uses a dry etching.

The upper electrode is thus formed of TiN so as to secure an excellent contact characteristic.

Moreover, by forming the upper electrode 1100 to 1300 Å thick, shear resistance inside the electrode has less influence on capacitance and a sufficient step difference to carry out succeeding processes smoothly is attained.

Referring to FIG. 3D, after removing the patterned first photoresist 108, a second photoresist 109 is formed on the third metal layer 105 including the fourth metal layer 107. The second photoresist 109 is then patterned using exposure and development.

A first metal wire 103b and a lower electrode 103a of a capacitor are defined by selectively removing the first to third metal layers 103 to 105 so as to expose a predetermined portion of the first insulating interlayer 102 by an etching process using the patterned second photoresist 109 as a mask. In this case, the etching process is a dry etch.

Referring to FIG. 3E, after removing the patterned second photoresist 109, a second insulating interlayer 110 is deposited over the substrate 101. Then, planarization is carried out thereon. In this case, the second insulating interlayer 110 is formed of IMO.

Subsequently, a plurality of contact holes 111a, 111b and 111c are formed by removing selectively the second insulating interlayer 110 so as to expose predetermined portions of the third and fourth metal layers 105 and 107. In this case, the contact holes 111a, 111b and 111c are formed using a dry etching process. During the dry etching process, the second insulating interlayer 110 has an etch rate at least twenty times as great as the fourth metal layer 107. Therefore, after the fourth metal layer 107 is exposed to the contact hole 111c, the second insulating interlayer 110 can be continuously etched to form another contact holes 111a and 111b.

Referring to FIG. 3F, a fifth metal layer is deposited on the second insulating interlayer 110 including the contact holes 111a-111c. A plug metal layer 112 is then formed inside each of the contact holes 111a-111c by etch back.

As the plug metal layer 112 is formed using etch-back, remaining metals after CMP or product cost increase is prevented.

Thereafter, a sixth metal layer 113 is deposited on the second insulating interlayer 110 including the plug metal layer 112. Second metal wires 113a are then formed by removing the sixth metal layer 113 selectively so each second metal wire 113a is connected to one of the plug metal layers 112.

As mentioned in the foregoing description, a method of fabricating a capacitor in a semiconductor device according to the present invention uses a nitride layer having a high dielectric constant to obtain a 1.0 fF/μm² density of a capacitor, which equals the density of the related art.

Accordingly, the present invention improves an interface characteristic between an upper electrode formed of TiN and a dielectric layer. Furthermore, since the present invention uses a line pattern, instead of a contact pattern, for defining a capacitor area, an area size variance is reduced and a cell area required for the capacitor area is minimized.

And, the present invention prevents leakage current degradation by oxidizing a surface of PE-N used as a dielectric layer.

Moreover, the present invention carries out a dry etching process for forming contacts and other circuit parts simultaneously, thereby reducing process steps and product cost.

Namely, the present invention reduces leakage current and avoids reducing capacitance and is suitable for fabricating analog devices such as ADC(Analog to Digital Convertor), DAC(Digital to Analog Convertor), and the like.

Further, a chip-matching characteristic of the present invention is excellent as uniformity of a dielectric layer on a wafer is improved. The process for integrating logic and DRAM devices has less process steps. And, the present invention is carried out at a low temperature. Therefore, the present invention is applicable to complex chip fabrication such as MML and the like.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A method of fabricating a capacitor in a semiconductor device comprising the steps of:
forming a first insulating interlayer on a semiconductor substrate having a transistor thereon;
depositing first to third metal layers on the first insulating interlayer successively;
depositing a first insulating layer on the third metal layer;
oxidizing a surface of the first insulating layer;
depositing a fourth metal layer on the first insulating layer;
selectively etching the first insulating layer and the fourth metal layer so as to expose a predetermined portion of the third metal layer;
selectively etching the first to third metal layers so as to expose a surface of the first insulating interlayer;
depositing a second insulating layer over the substrate;
forming a plurality of contact holes by selectively removing the second insulating layer so as to expose the third and fourth metal layers;
forming a metal plug in each of the contact holes; and
forming metal wires respectively connected to the metal plugs.

2. The method of claim 1, wherein the first metal layer is formed of Al, of which a thickness is 4500 to 5500 Å.

3. The method of claim 1, wherein the second metal layer is a barrier metal layer formed of Ti, of which a thickness is 50 to 150 Å.

4. The method of claim 1, wherein the third metal layer is an anti-reflective coating layer formed of TiN, of which a thickness is 500 to 700 Å.

5. The method of claim 1, wherein the first insulating layer is formed of PE-N, of which a thickness is 500 to 700Å.

6. The method of claim 1, wherein the first insulating layer is a dielectric layer.

7. The method of claim 1, wherein the step of oxidizing a surface of the first insulating layer is carried out by injecting O3 at a temperature of 250 to 350 Å.

8. The method of claim 1, wherein the fourth metal layer is formed of TiN, of which a thickness is 1100 to 1300 Å.

9. The method of claim 1, wherein the steps of etching the first insulating layer, the fourth metal layer, the second metal layer, and the third metal layer are carried out using a dry etch.

10. The method of claim 1, wherein the step of selectively etching the first to third metal layers so as to expose a surface of the first insulating interlayer is carried out to define a metal wire and a lower electrode.

11. The method of claim 1, the step of forming a metal plug comprises the steps of:
depositing a plug metal layer on the second insulating interlayer including the contact holes; and
removing the plug metal layer by etch-back so as to remain only in the contact holes.

12. The method of claim 1, wherein the contact holes are formed by dry etch.

13. The method of claim 12, wherein the dry etch is carried out until a thickness of the third metal layer is at least 300 to 500 Å thick.

14. A method of fabricating a capacitor in a semiconductor device comprising the steps of:
forming a first insulating interlayer on a semiconductor substrate having a transistor thereon;
depositing at least a first metal layer on the first insulating interlayer;
depositing a first insulating layer on the first metal layer;
oxidizing a surface of the first insulating layer;
depositing a second metal layer on the first insulating layer;
selectively etching the first insulating layer and the second metal layer so as to expose a predetermined portion of the first metal layer;
selectively etching the first metal layer so as to expose a surface of the first insulating interlayer;
depositing a second insulating layer over the substrate;
forming a plurality of contact holes by selectively removing the second insulating layer so as to expose the first and second metal layers;
forming a metal plug in each of the contact holes; and
forming metal wires respectively connected to the metal plugs.

15. A capacitor in a semiconductor device, comprising:
a first insulating interlayer formed on a semiconductor substrate having a transistor thereon;
first to third metal layers successively formed on the first insulating interlayer;
a first insulating layer formed on a portion of the third metal layer, a surface of the first insulating layer being oxidized;
a fourth metal layer formed on the first insulating layer;
a second insulating layer formed over the substrate and defining at least first and second contact holes exposing the fourth metal layer and the third metal layer;
a metal plug formed in each of the first and second contact holes; and metal wires respectively connected to the metal plugs.
